(19) United States
(12) Patent Application Publication
(10) Pub. No.: US 2008/0236872 A1
(43) Pub. Date: Oct. 2, 2008

(54) Printed Wiring Board, Process For Producing the Same and Semiconductor Device

(75) Inventors: Tatsuo Kataoka, Saitama (JP); Yoshikazu Akashi, Saitama (JP); Yutaka Iguchi, Tokyo (JP); Hiroaki Kurihara, Tokyo (JP); Naoya Yasui, Tokyo (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD., Tokyo (JP)

(21) Appl. No.: 11/632,793

(22) PCT Filed: Jun. 3, 2005
(86) PCT No.: PCT/JP05/10273

§ 371 Date: Jan. 18, 2007

(30) Foreign Application Priority Data
Jul. 29, 2004 (JP) 2004-222186

(51) Int. Cl. H05K 1/00; H05K 3/00

(52) U.S. Cl. 174/254; 29/829

(57) ABSTRACT

The printed wiring board of the present invention is a printed wiring board produced by selectively etching a base film having a base metal layer and a conductive metal layer, which are formed on an insulating film, through plural etching steps comprising a conductive metal etching step and a base metal etching step to form a wiring pattern and then bringing the base film having the thus formed wiring pattern into contact with a reducing aqueous solution containing a reducing substance, wherein the amount of a residual metal derived from the etching solution on the printed wiring board is not more than 0.05 μg/cm². According to the present invention, the metal derived from the etching solution is removed by the use of a reducing substance-containing solution. Therefore, the water rinsing step in the production process can be shortened, occurrence of migration attributable to the residual metal can be prevented, and a printed wiring board having high reliability can be efficiently produced.

### TECHNICAL FIELD

The present invention relates to a printed wiring board wherein a wiring pattern is directly formed on a surface of an insulating film, a process for producing the printed wiring board and a semiconductor device on which an electronic part is mounted. More particularly, the present invention relates to a printed wiring board formed from a base film of a two-layer structure consisting of an insulating film and a metal layer formed on a surface of the insulating film without interposing an adhesive layer, a process for producing the printed wiring board, and a semiconductor device wherein an electronic part is mounted on the printed wiring board.

### BACKGROUND ART

Wiring boards have been heretofore produced by the use of copper-clad laminates which comprises an insulating film such as a polyimide film and a copper foil laminated on a surface of the insulating film with an adhesive.

Such a copper-clad laminate is produced by thermally press-bonding a copper foil to an insulating film on a surface of which an adhesive layer has been formed. In the production of the copper-clad laminate, therefore, the copper foil must be handled separately. However, the nerve of the copper foil is lowered as the thickness of the copper foil is decreased, and the lower limit of the thickness of the copper foil that can be handled separately is about 12 to 35 μm. In the case where a copper foil having a thickness smaller than this is used, handling of the copper foil becomes very complicated, for example, a copper foil having a support needs to be used. Moreover, if a wiring pattern is formed using a copper-clad laminate obtained by bonding such a thin copper foil to a surface of an insulating film with an adhesive, warpage deformation of the resulting printed wiring board is brought about by heat shrinkage of the adhesive used for bonding the copper foil. In particular, with miniaturization and lightening of electronic equipment, thinning and lightening of printed wiring boards have been also promoted, and it is becoming impossible that the copper-clad laminates of three-layer structure consisting of an insulating film, an adhesive and a copper foil meet such printed wiring boards.

Then, instead of the copper-clad laminates of three-layer structure, laminates of two-layer structure wherein a metal layer is directly laminated onto a surface of an insulating film without interposing an adhesive are employed. Such a laminate of two-layer structure is produced by depositing a metal on a surface of an insulating film such as a polyimide film by means of vapor deposition, sputtering or the like. The surface of the metal thus deposited is coated with a photoresist, then the photoresist is exposed to light and developed to prepare a masking material, and using the masking material made of the photoresist, etching is performed, whereby a desired wiring pattern can be formed. The laminate of a two-layer structure is particularly suitable for producing an extremely fine wiring pattern having a wiring pattern pitch width of less than 30 μm because the metal layer is thin.

By the way, in a patent document 1 (Japanese Patent Laid-Open Publication No. 188495/2003), there is disclosed an invention of a process for producing a printed wiring board, comprising subjecting a metal-coated polyimide film (base film), which has a first metal layer (base metal layer) that is formed on a polyimide film by a dry film-forming method and a second metal layer (conductive metal layer) having conductivity that is formed on the first metal layer by plating, to etching to form a pattern, wherein after the etching, the etched surface is subjected to cleaning treatment with an oxidizing agent. In Example 5 of this patent document 1, an example wherein a nickel-chromium alloy was plasma deposited in a thickness of 10 nm and then copper was deposited in a thickness of 8 μm by plating is shown.

In the case where a wiring pattern is formed by the use of such a metal-coated polyimide film, it is necessary that the second metal layer (layer composed of conductive metal such as copper) that is present on the surface side is first etched to give a desired pattern and then the first metal layer (composed of nickel-chromium alloy or the like) is etched. For etching the first metal layer, an etching solution having oxidizing property such as potassium permanganate or potassium bichromate is used. It has been believed that by rinsing the printed wiring board in water after the first metal layer is etched with the etching solution having oxidizing property as above, the components contained in the etching solution can be removed, and in case of the conventional wiring boards, even if the components of the etching solution remained, they were not considered to exert an influence on the properties of the wiring boards. However, it has become apparent that as the pitch width of the wiring pattern is gradually narrowed, the value of insulation resistance between the wiring patterns is apt to vary when a voltage is applied between the wiring patterns of such narrow pitch width. The variation of the insulation resistance value is attributable to the metal residue or the like present on the polyimide film surface, and it has been found that the variation of the insulation resistance value due to migration or the like depends upon the amount of the metal present on the surface of the insulating film.

In such a printed wiring board, a base metal layer composed of a metal such as chromium or nickel is disposed between the conductive metal layer that is composed of copper or a copper alloy and forms a wiring pattern and the polyimide film that is an insulating film. In order to form a wiring pattern from such a composite metal layer composed of plural kinds of metals, the metals constituting the composite metal layer need to be dissolved through plural etching steps using different kinds of etching solutions. Particularly for etching the base metal layer containing a metal of chromium, nickel or the like, use of an etching solution containing an oxidizing inorganic compound such as potassium permanganate becomes necessary, and it has been found that such an oxidizing inorganic compound (metal, salt, metal oxide or the like) contained in the etching solution is liable to remain on the wiring pattern formed or the insulating film. Such an inorganic compound remaining in a slight amount on the wiring pattern formed or the insulating film contaminates a liquid agent used in the subsequent step for producing the printed wiring board, and besides, such an inorganic compound sometimes remains in the printed wiring board to the end of the production process. The remaining metal or inorganic compound derived from the etching solution sometimes causes migration occurring between the wiring patterns, and in order that the properties of the treating solution used in the subsequent step should not be lowered, it is necessary to remove such a metal as much as possible.

The metal or the inorganic compound, however, is hardly removed by water rinsing only. Moreover, in the recent printed wiring boards having wiring patterns of extremely fine pitches, rinsing in running water for a long period of time tends to cause deformation of the boards (wirings) due to water pressure of the like. In order to completely remove such a metal or an inorganic compound, however, rinsing in water needs to be continued over a long period of time, and on this account, there occur problems of lengthening of production line and lowering of productivity.

Patent document 1: Japanese Patent Laid-Open Publication No. 188495/2003

### DISCLOSURE OF THE INVENTION

### Problem to be Solved by the Invention

The present invention is intended to solve the problem peculiar to the printed wiring board using an extremely thin metal-coated insulating film, namely, the problem that if a voltage is continuously applied to the printed wiring board, which is formed using a base film (extremely thin metal-coated polyimide film) wherein an insulating film is coated with an extremely thin metal layer, for a long period of time, insulation resistance of the printed wiring board is lowered.

That is to say, it is an object of the present invention to provide a process for producing a printed wiring board whose insulation resistance value hardly varies, by the use of a base film (i.e., metal-coated polyimide film) in which an extremely thin metal layer is formed on at least one surface of an insulating film such as a polyimide film by sputtering or the like.

It is another object of the present invention to provide a printed wiring board which is produced by the above process and whose insulation resistance value hardly varies.

It is a further object of the present invention to provide a semiconductor device comprising an electronic part mounted on the above-mentioned printed wiring board.

### Means for Solving the Problem

The process for producing a printed wiring board of the present invention is a process comprising selectively etching a base film which comprises an insulating film, a base metal layer formed on at least one surface of the insulating film and a conductive metal layer formed on the base metal layer through plural etching steps comprising a conductive metal etching step for mainly dissolving the conductive metal and a base metal etching step for mainly dissolving the base metal, to form a wiring pattern, and then bringing the insulating film having the wiring pattern formed thereon into contact with a reducing aqueous solution containing a reducing substance.

In the process for producing a printed wiring board of the present invention, it is preferable that the base film is brought into contact with an etching solution that dissolves the conductive metal to form a wiring pattern, then brought into contact with a first treating solution that dissolves the metal for forming the base metal layer, subsequently brought into contact with a microetching solution that selectively dissolves the conductive metal, then brought into contact with a second treating solution that has a chemical composition different from that of the first treating solution and acts on the base metal layer-forming metal with higher selectivity than on the conductive metal, and further brought into contact with a reducing aqueous solution containing a reducing substance.

In the process for producing a printed wiring board of the present invention, it is preferable that the metal layer of the base film is selectively removed by etching to form a wiring pattern, and thereafter the base film is treated with a treating solution capable of dissolving and/or passivating the metal for forming the base metal layer and then brought into contact with a reducing aqueous solution containing a reducing substance.

In the process for producing a printed wiring board of the present invention, it is preferable that the base film is treated with a first treating solution capable of dissolving Ni contained in the base metal layer, then treated with a second treating solution capable of dissolving Cr contained in the base metal layer and capable of removing the base metal layer on the insulating film to remove, together with a surface layer of the insulating film, a sputtering metal remaining on the surface layer of the insulating film on which no wiring pattern has been formed, and further brought into contact with a reducing aqueous solution containing a reducing substance.

The printed wiring board of the present invention is a printed wiring board having a wiring pattern formed by selectively etching a base metal layer and a conductive metal layer, which are formed on at least one surface of an insulating film, through plural etching steps, wherein:

the amount of a residual metal derived from the etching solution on the printed wiring board is not more than 0.05 μg/cm².

In the printed wiring board of the present invention, it is preferable that the width of the lower end of the conductive metal layer in a section of the wiring pattern is smaller than the width of the upper end of the base metal layer in a section thereof, and the amount of the residual metal derived from the etching solution on the printed wiring board is not more than 0.05 μg/cm².

In the printed wiring board of the present invention, it is preferable that the base metal layer that constitutes the wiring pattern is formed so as to protrude in the width direction more than the conductive metal layer that constitutes the wiring pattern, and the amount of the residual metal derived from the etching solution on the printed wiring board is not more than 0.05 μg/cm².

In the printed wiring board of the present invention, it is preferable that the thickness of the insulating film on which no wiring pattern has been formed is smaller by 1 to 100 nm than the thickness of the insulating film on which the wiring pattern has been formed, and the amount of the residual metal derived from the etching solution on the printed wiring board is not more than 0.05 μg/cm².

In the present invention, it is particularly preferable that the amount of the residual metal derived from the etching solution in the printed wiring board is in the range of 0.000002 to 0.03 μg/cm².

The semiconductor device of the present invention is a semiconductor device comprising an electronic part mounted on the above-mentioned printed wiring board in which the amount of the metal derived from the etching solution is extremely small.

For selectively etching the base film having a base metal layer and a conductive metal layer, which are formed on at least one surface of an insulating film, it is necessary to etch the conductive metal layer and the base metal layer through plural etching steps. The etching solution, which contains an oxidizing compound such as potassium permanganate and is used for mainly etching the base metal layer in the above etching steps, is hardly removed only by the rinsing step subsequent to the etching steps. Therefore, in the printed wiring board produced by way of the usual water rinsing step, the metal derived from the etching solution, such as manganese, remains in a slight amount, and the amount of the residual metal derived from the etching solution cannot be decreased to not more than 0.05 μg/cm² by the usual water rinsing step.

In the present invention, the base film in which a base metal layer and a conductive metal layer are laminated in this order on at least one surface of an insulating film is selectively etched to form a wiring pattern composed of the base metal layer and the conductive metal layer, and then an oxidizing metal or metal compound derived from the etching solution, e.g., manganese contained in the etching solution used for etching the base metal layer, is treated with an aqueous solution containing a reducing substance. By performing the treatment with such an aqueous solution containing a reducing substance, the metal or the metal compound derived from the etching solution becomes to be very easily removed by rinsing in water, and the amount of the residual metal derived from the etching solution, which is present on the surface of the printed wiring board after the water rinsing, can be decreased to not more than 0.05 μg/cm², preferably in the range of 0.000002 to 0.03 μg/cm². By cleaning the surface of the printed wiring board with the aqueous solution containing a reducing substance after formation of the wiring pattern, as described above, the amount of the residual metal derived from the etching solution can be remarkably decreased, so that a chemical solution used in the subsequent step is not contaminated, and deterioration of appearance and quality of the printed wiring board of the present invention can be effectively prevented. Further, variation of insulation resistance value between wiring patterns with time can be reduced, and a printed wiring board and a circuit board having high reliability can be obtained.

### EFFECT OF THE INVENTION

In the process for producing a printed wiring board of the present invention, the board having a wiring pattern formed through plural etching steps is cleaned with an aqueous solution containing a reducing substance. By cleaning the board with such a reducing substance-containing aqueous solution, a metal derived from the etching solution and adhering to the board surface can be removed very efficiently. That is to say, in the production of the printed wiring board of the present invention, a base film in which a base metal layer and a conductive metal layer formed on a surface of the base metal layer are formed on at least one surface of an insulating film is used, and the base metal layer and the conductive metal layer are selectively etched in plural etching steps using different etching solutions to form a wiring pattern. For selectively etching the base metal present on the insulating film, an etching solution containing an oxidizing metal compound such as potassium permanganate or sodium permanganate is used. On this account, on the surface of the resulting printed wiring board, a metal derived from the etching solution remains though it is in a slight amount, and because of a slight amount of such a residual metal derived from the etching solution, migration is apt to take place between the wiring patterns. Moreover, the residual metal also becomes a cause of contamination of a treating solution used in the subsequent step. Such a residual metal derived from the etching solution is hardly removed by rinsing in water. The printed wiring board is continuously produced in the form of a long tape, so that there is limitation on the water rinsing step allotted, and by the water rinsing step in the usual production process of a printed wiring board, the amount of the residual metal derived from the etching solution, which is present on the surface of the printed wiring board, cannot be decreased to such a value as defined in the present invention.

The present invention has been accomplished based on the finding that the residual metal derived from the etching solution can be efficiently removed by the use of a reducing aqueous solution containing a reducing substance. In the present invention, a base film having a conductive metal layer such as a layer of copper or a copper alloy on at least one surface of an insulating film by way of a base metal layer such as a layer of nickel or chromium is used, and the base metal layer and the conductive metal layer are selectively etched in plural etching steps using different kinds of plural etching solutions, to form a wiring pattern. Thereafter, the film surface is treated with a reducing aqueous solution containing a reducing substance such as a reducing organic acid to remove the residual metal derived from the etching solution

Consequently, on the surface of the printed wiring board produced by the process of the present invention, the residual metal derived from the etching solution is present in an extremely small amount, migration attributable to the residual metal does not take place, and a treating solution used in the subsequent step is not contaminated with the residual metal.

As described above, the residual metal derived from the etching solution is efficiently removed from the surface of the printed wiring board of the present invention. Accordingly, even if the printed wiring board of the present invention is used for a long period of time, the value of insulation resistance between the wiring patterns hardly varies. Further, change of properties of the wiring pattern due to the residual metal hardly takes place.

Furthermore, because the value of electrical resistance between the wiring patterns formed in the printed wiring board is stable in spite of a lapse of time, the semiconductor device of the present invention can be stably used for a long period of time.

### BRIEF DESCRIPTION OF THE DRAWINGS

FIG. 1 is a flow chart showing examples of steps for producing a printed wiring board of the present invention.

FIG. 2 is a group of views showing examples of sections of wiring patterns in the steps for producing a printed wiring board of the present invention.

FIG. 3 is a group of views schematically showing examples of sections of wiring patterns formed by the process of the present invention.

### DESCRIPTION OF REFERENCE NUMERALS

11: insulating film
12: base metal layer
16: plating layer
17: base supporting part having sectional shape of trapezoid
20: conductive metal layer
22: masking material

### BEST MODE FOR CARRYING OUT THE INVENTION

The printed wiring board of the present invention and the process for producing the printed wiring board are described in detail hereinafter in accordance with the procedure of the production process.

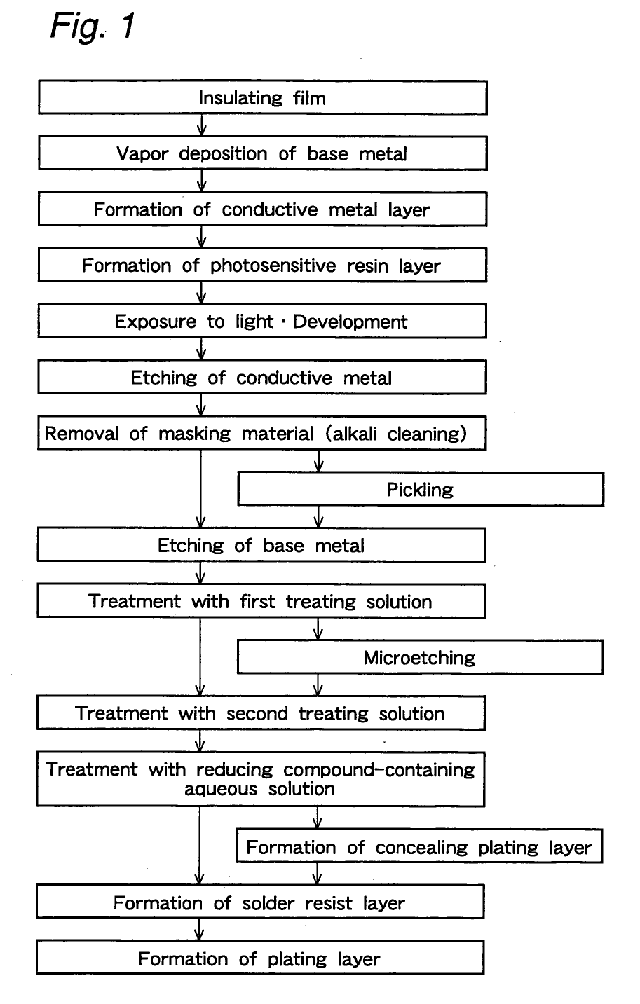

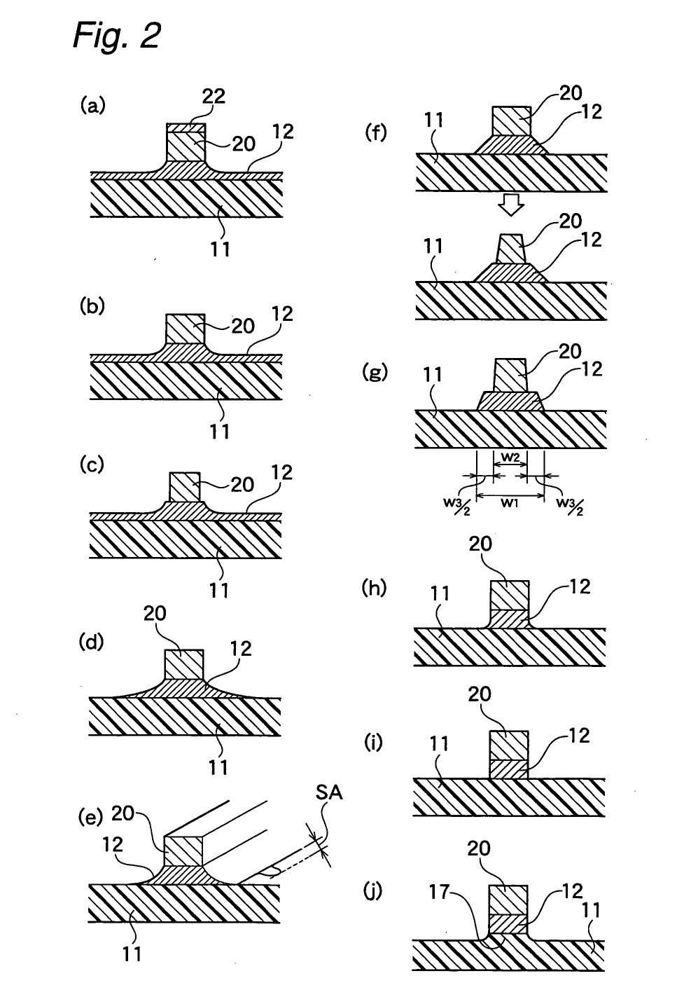

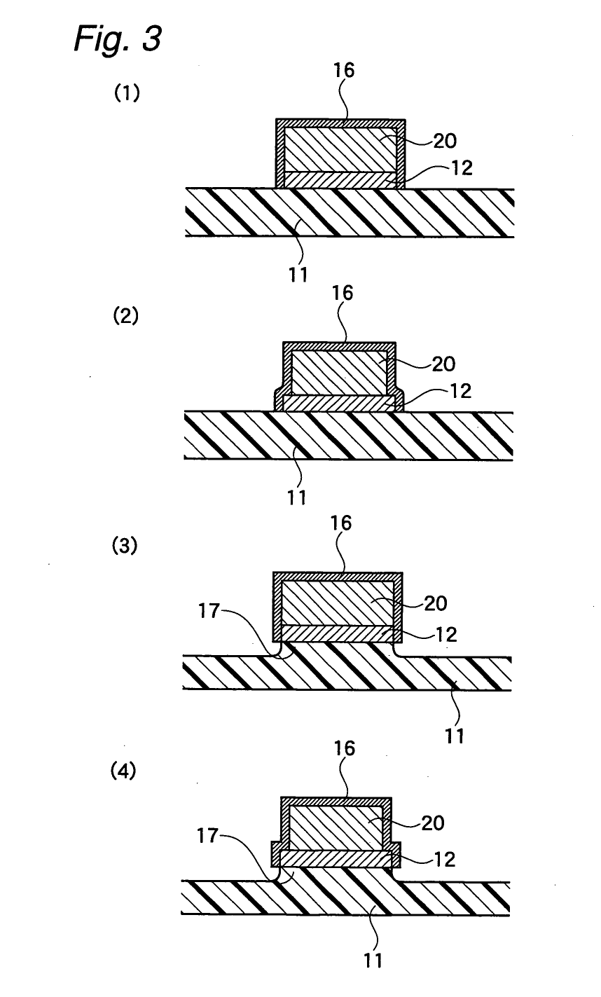

FIG. 1 is a flow chart showing examples of steps for producing the printed wiring board of the present invention. FIG. 2 is a group of sectional views showing examples of sectional shapes of wiring patterns in the steps for producing the printed wiring board. FIG. 3 is a group of sectional views schematically showing examples of sectional shapes of wiring patterns in the printed wiring board produced by the process of the present invention. Referring to FIG. 2 and FIG. 3, common members are given common numerals, and numeral 11 designates an insulating film, numeral 12 designates a base metal layer, numeral 16 designates a plating layer, numeral 20 designates a conductive metal layer, and numeral 22 designates a masking material.

In the production of the printed wiring board of the present invention, a base film having a base metal layer formed on at least one surface of an insulating film and having a conductive metal layer formed on a surface of the base metal layer is used.

Examples of the insulating films for constituting the base film include films of polyimide, polyimideamide, polyester, polyphenylene sulfide, polyether imide, fluororesin and liquid crystal polymer. That is to say, the insulating film has heat resistance of such a degree that it is not deformed by heating in the formation of the base metal layer or the like. Further, the insulating film has acid resistance and alkali resistance of such a degree that it is not eroded by an etching solution used for etching and an alkali solution used for cleaning. As the insulating film having such properties, a polyimide film is preferable.

The insulating film has an average thickness of usually 7 to 150 μm, preferably 7 to 50 μm, particularly preferably 15 to 40 μm. The printed wiring board of the present invention is suitable to form a thin board, so that it is preferable to use a thinner polyimide film. In order to improve adhesion to the following base metal layer, the surface of the insulating film may be subjected to roughening treatment using a hydrazine-KOH solution, plasma treatment or the like.

On the surface of the insulating film, a base metal layer is formed. The base metal layer is formed on at least one surface of the insulating film, and therefore, any of a film (single-sided base film) having a structure in which the base metal layer and a conductive metal layer are laminated on one surface of the insulating film and a film (double-sided base film) having a structure in which the base metal layer and a conductive metal layer are laminated on both surfaces of the insulating film is employable.

By providing the base metal layer in the base film, adhesion of a conductive metal layer formed on the surface of the base metal layer to the insulating film is improved.

In the present invention, the base metal layer can be formed from a metal, such as copper, nickel, chromium, molybdenum, tungsten, silicon, palladium, titanium, vanadium, iron, cobalt, manganese, aluminum, zinc, tin or tantalum. These metals can be used singly or in combination. In the present invention, the base metal layer is particularly preferably formed from nickel, chromium or an alloy containing this metal. It is preferable to form the base metal layer on the surface of the insulating film by a film-forming method of dry process, such as vapor deposition or sputtering. The thickness of the base metal layer is in the range of usually 1 to 100 nm, preferably 2 to 50 nm. The base metal layer is provided for the purpose of stably forming a conductive metal layer thereon, and is preferably formed by allowing the base metal to collide with the insulating film, a part of said base metal having kinetic energy of such a degree that it physically thrusts into the insulating film surface. In the present invention, therefore, the base metal layer is particularly preferably a sputtering layer of the base metal.

On the surface of the base metal layer, a conductive metal layer is formed. The conductive metal layer is usually formed from copper or a copper alloy. The conductive metal layer can be formed by depositing copper or a copper alloy on the surface of the base metal layer through a plating method. Examples of the plating methods employable herein for forming the conductive metal layer include methods of wet process, such as electroplating and electroless plating, and methods of dry process, such as sputtering and vapor deposition. The conductive metal layer may be formed by any of the above methods. The conductive metal layer can be formed also by combining the dry process with the wet process.

In the present invention, it is particularly preferable to form the conductive metal layer by a wet plating method such as electroplating or electroless plating. The average thickness of the conductive metal layer thus formed is in the range of usually 0.5 to 40 μm, preferably 1 to 18 μm, more preferably 2 to 12 μm. In the case where the wet process and the dry process are combined to form the conductive metal layer, a sputtering conductive metal layer is first formed on the surface of the base metal layer by sputtering or the like, and then on the surface of the sputtering conductive metal layer, a wet process conductive metal layer is formed. In this case, the average thickness of the sputtering conductive metal layer is in the range of usually 0.5 to 17.5 μm, preferably 1.5 to 11.5 μm, and the total average thickness of the sputtering conductive metal layer and the wet process conductive metal layer is set in the aforesaid range. The thus formed conductive metal layers are united in a body and inseparable even if the conductive metal deposition methods are different from each other, and they function equally to each other in the formation of a wiring pattern.

The total average thickness of the base metal layer and the conductive metal layer formed as above is in the range of usually 0.5 to 40 μm, preferably 1 to 18 μm, more preferably 2 to 12 μm. The average thickness ratio of the base metal layer to the conductive metal layer is in the range of usually 1:40000 to 1:10, preferably 1:5000 to 1:100.

In the production of the printed wiring board of the present invention, the base film in which the base metal layer and the conductive metal layer are formed on at least one surface of the insulating film is used, and the base metal layer and the conductive metal layer are selectively etched through plural etching steps to form a wiring pattern.

The wiring pattern can be obtained by forming a photosensitive resin layer on the conductive metal layer of the base film, then light-exposing and developing the photosensitive resin to form a desired pattern made of the photosensitive resin and etching the metal layers using the pattern as a masking material.

As etching steps, a conductive metal etching step for mainly etching the conductive metal layer and a base metal etching step for mainly etching the base metal are carried out.

The conductive metal etching step is a step for etching copper or a copper alloy constituting the conductive metal layer, and the etching agent used herein is an etching agent for copper or a copper alloy that is the conductive metal (i.e., Cu etching solution).

Examples of the conductive metal etching agents include an etching solution containing ferric chloride as a main component, an etching solution containing cupric chloride as a main component, and an etching agent such as sulfuric acid+hydrogen peroxide. The etching agent for the conductive metal can etch the conductive metal layer with excellent selectivity to form a wiring pattern, and besides, it has a considerable etching function for the base metal present between the conductive metal layer and the insulating film.

In the conductive metal etching step, the treatment temperature is in the range of usually 30 to 55° C., and the treatment time is in the range of usually 5 to 120 seconds. By performing etching using the conductive metal etching agent as above, a wiring pattern having a sectional structure in which the conductive metal layer 20 has been mainly etched as shown in, for example, FIG. 2(a) is formed.

By performing the conductive metal etching as above, the conductive metal layer 20 present on the surface of the base film is mainly etched, whereby a wiring pattern having a shape resembling to the shape of the masking material used is formed. Although the base metal layer 12 present below the conductive metal layer 20 is also etched considerably, the base metal layer 12 is not removed completely in this conductive metal etching step.

After the conductive metal is mainly and selectively etched using the masking material 22 composed of a cured product of a photosensitive resin, the masking material 22 composed of a cured product of a photosensitive resin is treated with a cleaning solution, e.g., an aqueous solution containing an alkali such as sodium hydroxide or potassium hydroxide, specifically an aqueous solution containing NaOH+Na₂CO₃ or the like, whereby the masking material can be removed. The wiring pattern from which the masking material has been removed has such a sectional shape as shown in FIG. 2(b).

In the present invention, the conductive metal layer is mainly removed along the pattern of the masking material as above, and thereafter, the base metal layer is dissolved and removed in the base metal etching step for mainly and selectively etching the base metal layer, to form a wiring pattern. However, prior to the base metal etching step, a pickling step (microetching step) can be provided. That is to say, after the conductive metal layer is mainly and selectively etched in the conductive metal etching step, the pattern composed of the photosensitive resin which was used as the masking material in the conductive metal etching step is removed by, for example, alkali cleaning. By such contact with the alkali cleaning solution, however, an oxide film is sometimes formed on the conductive metal layer surface or the base metal layer surface. Further, the conductive metal layer (Cu) surface (top of wiring pattern) that has been in contact with the masking material composed of a cured product of a photosensitive resin does not have a history of contact with an etching agent, so that it sometimes has an activity different from that of a side of the wiring pattern. Therefore, after the conductive metal etching step, pickling (microetching) is carried out to make the wiring pattern surface (whole surface) uniform, and as a result, etching of high accuracy can be carried out in the subsequent step.

However, if the contact time with the etching solution is long in the pickling step, copper or a copper alloy that forms the wiring pattern is dissolved in a large amount, and hence, the wiring pattern itself becomes thin. In the case where pickling is carried out in this stage, therefore, the time of contact of the etching solution with the wiring pattern in the pickling step is in the range of usually 2 to 60 seconds. The wiring pattern having been subjected to pickling of first time as above has such a sectional shape as shown in FIG. 2(c).

The conductive metal etching step is performed as above, then the pickling step (microetching of first time) is performed when needed, and thereafter, the base metal etching step is performed. In this base metal etching step, the base metal layer is mainly dissolved and removed, and moreover, a residual base metal is passivated.

The base metal layer is composed of a metal, such as copper, nickel, chromium, molybdenum, titanium, vanadium, iron, cobalt, aluminum, zinc, tin or tantalum, or an alloy containing such a metal. The metal that forms the base metal layer is selectively dissolved by the use of an etching solution suitable for the base metal layer-forming metal, and in addition, the base metal layer-forming metal remaining in a slight amount on the insulating film is passivated.

In the case where the base metal layer that is a target of the base metal etching is composed of, for example, nickel and chromium, the nickel can be dissolved and removed by the use of a first treating solution (first treating solution capable of dissolving Ni) such as a sulfuric acid/hydrochloric acid mixed solution, and the chromium can be dissolved and removed by the use of a second treating solution (second treating solution capable of dissolving Cr) such as a potassium permanganate+KOH aqueous solution.

Examples of the first treating solutions capable of dissolving Ni in the present invention include a sulfuric acid/hydrochloric acid mixed solution having each concentration of about 5 to 15% by weight and a mixed solution of potassium persulfate and sulfuric acid.

By the treatment using the first treating solution, nickel among the metals that constitute the base metal layer is mainly dissolved and removed. In the treatment using the first treating solution, the treatment temperature is in the range of usually 30 to 50° C., and the treatment time is in the range of usually 5 to 40 seconds.

By the above treatment, a base metal in the form of a protrusion remaining on the side surface of the wiring pattern and/or a base metal remaining between the wirings is dissolved and removed, as shown in, for example, FIG. 2(d). As a result, the distance between the base metal layer and another base metal layer that constitutes the neighboring wiring pattern becomes a value approximate to a prescribed value (design value). That is to say, the distance between the base metal layers constituting the wiring patterns varies depending upon a design width of a wiring pitch to be formed, but in case of a wiring pitch of, for example, 30 μm (design line width: 15 μm, design space width: 15 μm), the shortest distance between the base metal layers, as actually measured from an electron micrograph (SEM photograph), is frequently in the range of 5 to 18 μm. This shortest distance actually measured is in the range of 33% to 120% of the design value, and by more preferably setting the conditions, the shortest distance between the base metal layers can be made in the range of 10 to 16 μm, that is, in the range of 66.7 to 106.7% of the design value. In the case of a wiring pitch of, for example, 100 μm (design line width: 50 μm, design space width: 50 μm), the wiring pattern width actually measured can be made in the range of 10 to 120% of the design value.

The expression “a base metal in the form of a protrusion remaining is dissolved and removed in the treatment using the first treating solution” means that a base metal is dissolved so that the distance (SA) from a wiring pattern-forming continuous line formed by the base metal layer of the wiring pattern to the tip of a protruded part that protrudes in the width direction from the wiring pattern-forming continuous line should become 0 to 6 μm (0 to 40% of design space width), preferably 0 to 5 μm, more preferably 0 to 3 μm, most preferably 0 to 2 μm as shown in FIG. 2(e). Therefore, when the distance from the wiring pattern-forming continuous line to the tip of the protruded part is within the above range, such a part is considered to form the wiring pattern-forming continuous line and is not called a “protrusion” in the present invention.

On the surface of the wiring pattern formed in the present invention, a plating layer is formed in order to prevent oxidation in the subsequent step or in order to form an alloy layer for bonding an IC chip or the like, and in the case where such a plating layer is formed, the width of the narrowest part between the plating layers formed on the neighboring wiring patterns (shortest distance between wiring patterns) is desirably secured to be at least 5 μm.

After the treatment using the first treating solution is carried out as above, treatment using a second treating solution is carried out. However, prior to the treatment using the second treating solution, microetching can be carried out.

In the case where the microetching is carried out in the present invention, an etching solution used for etching Cu that is a conductive metal, such as HCl or H₂SO₄, is employable as the microetching solution. Further, potassium persulfate (K₂S₂O₈), sodium persulfate (Na₂S₂O₈), sulfuric acid+H₂O₂, or the like is also employable. In the present invention, potassium persulfate (K₂S₂O₈), sodium persulfate (Na₂S₂O₈), or sulfuric acid+H₂O₂ is particularly preferably used as the microetching solution.

By performing microetching as above, Cu that is a conductive metal for forming the wiring pattern is selectively etched as shown in FIG. 2(f), but Ni or Cr that is a base metal is not etched so much. In this microetching step, the conductive metal layer (Cu layer) 20 constituting the wiring pattern is mainly etched so as to slightly retreat from the periphery of the wiring pattern to the center thereof, while the base metal layer 12 constituting the wiring pattern is hard to be comparatively etched. Consequently, in the wiring pattern formed through this microetching step, an obvious difference in width is made between the lower end of the conductive metal layer 20 constituting the wiring pattern and the upper end of the base metal layer 12 constituting the wiring pattern. That is to say, a part of the wiring pattern, which is composed of the conductive metal (Cu), is retreated toward the sectional center of the wiring pattern by microetching, but because the base metal layer of the wiring pattern is hard to be dissolved by microetching, the shape of the wiring pattern composed of the base metal layer is maintained. Accordingly, the wiring pattern formed through the microetching step has such a shape that a projected part of the base metal layer is formed around the wiring pattern composed of the conductive metal layer.

By providing the microetching step in the course of the base metal layer etching step using the first treating solution and the second treating solution as above, the width W1 of the upper end of the base metal layer and the width W2 of the lower end of the conductive metal layer 20 obviously differ from each other, as shown in FIG. 2(g), and a difference W3 (value of W1−W2, i.e., 2×(W3/2)) is in the range of usually 0.05 to 2.0 μm, preferably 0.2 to 1.0 μm.

By carrying out the microetching between the treatment of the base metal layer with the first treating solution and the treatment of the base metal layer with the second treating solution having a composition different from that of the first treating solution, there is obtained a wiring pattern with a belt-shaped projected part having a width of W3×½, composed of the base metal layer 12 and formed around the wiring pattern composed of the conductive metal layer 20 of Cu or the like.

This microetching step is an arbitrary step, and if the microetching step is not carried out, such a belt-shaped projected part composed of the base metal layer 12 as shown in FIG. 2(h) is not formed in the wiring pattern. By treating this projected part with the second treating solution, occurrence of migration can be inhibited.

After the microetching is carried out as above when needed, treatment using the second treating solution is carried out.

The second treating solution is a treating solution capable of dissolving Cr contained in the base metal layer and capable of passivating residual Cr if Cr remains.

That is to say, although most of Ni that constitutes the base metal layer 12 is dissolved and removed by performing the treatment using the first treating solution (and further by performing the microetching when needed), Cr that is a metal for constituting the base metal layer 12 still remains on the insulating film 11. If such Cr remains between the wiring patterns, the value of insulation resistance between the wiring patterns is not stabilized. Therefore, the second treating agent containing a component capable of dissolving and removing Cr contained in the base metal layer 12 on the insulating film 11 or capable of passivating residual Cr even if Cr remains is employed.

The second treating agent used herein is a treating solution capable of dissolving and removing Cr contained in the base metal layer and capable of passivating residual Cr even if Cr remains on the insulating film surface. Examples of the second treating solutions include a potassium permanganate·KOH aqueous solution and a sodium permanganate+NaOH aqueous solution. When the potassium permanganate+KOH aqueous solution is used as the second treating solution, the concentration of potassium permanganate is in the range of usually 10 to 60 g/liter, preferably 25 to 55 g/liter, and the concentration of KOH is in the range of preferably 10 to 30 g/liter. In the treatment using the second treating solution in the present invention, the treatment temperature is in the range of usually 40 to 70° C., and the treatment time is in the range of usually 10 to 60 seconds.

By performing the treatment using the second treating solution as above, most of Cr that constitutes the base metal layer 12 is dissolved and removed, as shown in FIG. (i). Even if Cr remains in a slight amount on the insulating film 11, this Cr can be passivated. That is to say, by performing the treatment using the second treating solution, most of Cr remaining as the base metal layer 12 on the surface of the insulating film 11 is dissolved, and Cr remaining in a thickness of probably several tens Å on the surface of the insulating film can be oxidized and passivated.

Further, by preferably using the second treating solution, the surface of the insulating film 11 can be chemically polished with the second treating solution, as shown in FIG. 2(j). By preferably using the second treating solution, therefore, the base metal layer 12 can be removed, and moreover, the insulating film 11 can be cutted (dissolved and removed) in a depth of usually 1 to 100 nm, preferably 5 to 50 nm, from the surface of the insulating film. By the use of the second treating solution as above, Cr remaining on a surface layer of the insulating film 11 can be removed together with the surface layer of the insulating film. Accordingly, when the second treating solution is preferably used, the thickness of the insulating film 11 on which no wiring pattern has been formed is smaller by 1 to 100 nm, preferably 2 to 50 nm, than the thickness of the insulating film on which the wiring pattern has been formed. The base metal layer 12 and the insulating film 11 corresponding to the wiring pattern are protected from the second treating solution by the conductive metal layer 20.

As shown in FIG. 2(j), the wiring pattern of the printed wiring board obtained without performing the aforesaid microetching has a section in which the width of the lower end of the wiring pattern composed of the conductive metal layer 20 is the same or almost the same as the width of the upper end of the base metal layer 12. However, the surface of the insulating film 11 (polyimide film) on which no wiring pattern has been formed is cutted in a depth of usually 1 to 100 nm, preferably 2 to 50 nm, and therefore, in the insulating film on which the wiring pattern has been formed, a base supporting part 17 having a sectional shape of trapezoid and having a height of 1 to 100 nm, preferably 2 to 50 nm, is formed.

After the treatment using the second treating solution, generally, independent Ni is not observed on the insulating film between the wiring patterns, but Cr sometimes remains thereon in a slight amount. Such Cr, however, is passivated, and by virtue of the passivated Cr, insulation between the wiring patterns is not impaired.

After the wiring pattern is formed using various etching agents in plural etching steps as above, the printed wiring pattern is rinsed in water, but on the surface of the printed wiring board, a metal derived from the etching solution used for forming the wiring pattern remains.

As the etching solution particularly used for etching the base metal layer, an etching solution containing an oxidizing inorganic compound such as potassium permanganate is highly useful, and if such an etching solution containing an oxidizing inorganic compound is used, a metal derived from the etching solution remains on the surface of the printed wiring board. That is to say, after the etching step is completed, the printed wiring board is subjected to rinsing in water, but the metal derived from the etching solution is not removed only by the usual water rinsing step subsequent to the etching step, and it remains on the surface of the printed wiring board. This remaining metal causes contamination of a treating solution used in the subsequent step, and moreover, because of the remaining metal, migration is apt to take place, that is, this metal may cause lowering of reliability of the printed wiring board. The metal derived from the etching solution is a metal for composing the oxidizing inorganic compound used in the final etching treatment and is specifically manganese or the like. Such a metal sometimes forms a metallic compound such as an oxide.

In the present invention, after the wiring pattern is formed as above, the insulating film having the wiring pattern formed thereon is brought into contact with a reducing aqueous solution containing a reducing substance.

The reducing substance used herein is, for example, an organic acid having reducing ability, and examples of the organic acids having reducing ability include oxalic acid, citric acid, ascorbic acid and an organic carboxylic acid. These organic acids having reducing ability can be used singly or in combination. These organic acids may form salts.

The organic acid having reducing ability is used by dissolving it in water to a concentration having no influence on the wiring pattern formed and capable of removing the residual metal derived from the etching solution, and is used by dissolving it in water to a concentration of usually 2 to 10% by weight, preferably 3 to 5% by weight.

Although the method to bring the reducing aqueous solution containing such an organic acid having reducing ability into contact with the wiring pattern is not specifically restricted, it is preferable to adopt a method of uniformly bringing the reducing treating solution into contact with the wiring pattern. For example, various methods, such as a method of immersing the insulating film having the wiring pattern formed thereon in the treating solution and a method of spraying the treating solution onto the insulating film having the wiring pattern formed thereon, are adoptable, and these methods may be combined.

The reducing treating solution is adjusted to a temperature in the range of usually 25 to 60° C., preferably 30 to 50° C., and the time of contact with the reducing treating solution having been adjusted to such a temperature is in the range of usually 2 to 150 seconds, preferably 10 to 60 seconds. By the contact with the reducing treating solution, the metal derived from the etching solution and remaining on the wiring pattern and the insulating film surface can be efficiently removed.

Although the wiring board (insulating film and wiring pattern formed thereon) having been subjected to the contact treatment with the reducing treating solution can be treated in the next step, it is preferable to carry out rinsing in water prior to the next step.

The time required for this water rinsing step can be made shorter than the time required for the usual water rinsing step because most of the metal derived from the etching solution and remaining on the surface has been already removed by the contact with the reducing treating solution as described above. In the present invention, the water rinsing time after the treatment with the reducing treating solution is in the range of usually 2 to 60 seconds, preferably 15 to 40 seconds, that is, the water rinsing time can be shortened to about ½ to 1/30 as compared with the case where the treatment with an aqueous solution containing a reducing substance is not carried out.

In the present invention, etching is carried out in plural steps using etching solutions of different compositions, then treatment with an aqueous solution containing a reducing substance is carried out, and further rinsing in water is preferably carried out, whereby the amount of the residual metal derived from the etching solution and present on the surface of the printed wiring board becomes not more than 0.05 μg/cm², preferably 0.000002 to 0.03 μg/cm². That is to say, the oxidizing inorganic compound used for mainly etching the base metal layer tends to partially remain on the surface of the board and cannot be completely removed by water rinsing only.

In the present invention, the amount of the residual metal derived from the etching solution and present on the surface of the printed wiring board was determined in the following manner. (1) A long film carrier tape for mounting electronic components was cut to give a piece having one wiring pattern as a sample (e.g., a tape having a width of 35 mm was cut to give a piece having a length of 47.5 mm corresponding to 10 perforations and having one wiring pattern). (2) The sample was placed in pure water (100 cc) that is a dissolving liquid and boiled at 100° C. for 5 hours to extract Mn contained in the sample into hot water. (3) The amount of Mn dissolved in hot water was measured by analytical measurement using ICP-MS (inductively coupled plasma mass analysis device, ICP mass) to determine the amount of Mn extracted, and the resulting total amount of Mn was divided by the whole area (total of both sides) of the sample cut out, to obtain the amount of the residual metal.

By performing contact with the aqueous solution containing a reducing substance as in the present invention and then performing rinsing in water, the amount of the residual metal derived from the etching solution and present on the surface of the printed wiring board can be reduced to not more than 0.05 μg/cm², and in addition, by preferably controlling the conditions of the contact with the solution containing a reducing substance and the rinsing in water, the amount of the residual metal can be reduced to the range of 0.000002 to 0.03 μg/cm². Such an amount of the residual metal derived from the etching solution is a value, which cannot be attained in a short period of time by the usual water rinsing.

The wiring pattern formed in the printed wiring board is coated with a resin protective layer in such a manner that the terminal portion is exposed. However, prior to formation of the resin protective layer, concealing plating can be carried out so as to cover at least the base metal layer of the wiring pattern formed. That is to say, after the wiring pattern is formed, the printed wiring board is treated with an aqueous solution containing a reducing substance so as to remove the metal derived from the etching solution remaining on the wiring pattern formed and the insulating film exposed, then water rinsing is performed, and after the water rinsing and before the formation of a resin coating layer, a plating layer can be formed so as to conceal the exposed portion of the base metal layer that is a lower part of the wiring pattern.

The concealing plating layer is formed on at least the base metal layer that is a lower part of the wiring pattern, and this concealing plating layer may be formed on all over the wiring pattern. Examples of the concealing plating layers formed as above include a tin plating layer, a gold plating layer, a nickel-gold plating layer, a solder plating layer, a lead-free solder plating layer, a Pd plating layer, a Ni plating layer, a Zn plating layer and a Cr plating layer. The plating layer may be a single layer or a composite plating layer composed of a laminate of plural plating layers. In the present invention, a tin plating layer, a gold plating layer, a nickel plating layer or a nickel-gold plating layer is particularly preferable. After a resin protective layer is formed on the wiring pattern in such a manner that the terminal portion is exposed, the concealing plating layer may be formed on the exposed terminal portion.

Although the thickness of the concealing plating layer can be properly selected according to the type of the plating, it is in the range of usually 0.005 to 5.0 μm, preferably 0.005 to 3.0 μm. After the whole surface is subjected to concealing plating and then a resin protective layer is formed in such a manner that the terminal portion is exposed, the terminal portion exposed from the resin protective layer may be subjected to plating again using the same metal. Also by the formation of the concealing plating layer having the above thickness, occurrence of migration from the base metal layer constituting the wiring pattern can be prevented.

The concealing plating layer can be formed by electroplating, electroless plating or the like.

By performing concealing plating on the wiring pattern as above, the passivated surface and side wall of the base metal layer present on the insulating film side of the wiring pattern are concealed by the concealing plating layer, and even if a potential difference is produced between different metals, occurrence of migration from the base metal layer can be effectively prevented because the insulation resistance between the wiring patterns is sufficiently high. By performing concealing plating in the above manner, even the side wall of the base metal layer is covered with the concealing plating layer, and the base metal is not exposed. Therefore, reliability on the insulation between the wiring patterns becomes high, and insulation failure with time due to migration or the like hardly takes place. The concealing plating is carried out for the main purpose of preventing occurrence of migration from the base mean layer. However, the purpose is not limited to concealing of the base metal layer, and the concealing plating may be carried out for the purpose of preventing occurrence of pitting corrosion in the subsequent step for plating a terminal portion.

After the concealing plating is carried out as above when needed, a resin protective layer is formed so as to cover the wiring pattern except the terminal portion and the insulating film where the wiring pattern has been formed. This resin protective layer can be formed by, for example, applying a solder resist ink onto the desired portions using screen printing technique or shaping a resin film with an adhesive layer into a desired shape and then sticking the thus shaped resin film.

After the resin protective layer such as a solder resist layer is formed as above, a plating layer is formed on the wiring pattern surface exposed from the resin protective layer. That is to say, the terminal portion exposed from the solder resist layer or the resin protective layer is subjected to plating. This plating is carried out in order to electrically connect the terminal of the printed wiring board to a bump electrode or the like formed on an electronic component when the electronic component is mounted on the printed wiring board and in order to establish electrical connection between the printed wiring board and another member when the printed wiring board on which the electronic component has been mounted (semiconductor device) is incorporated into electronic equipment.

Examples of the plating layers formed as above include a tin plating layer, a gold plating layer, a silver plating layer, a nickel-gold plating layer, a solder plating layer, a lead-free solder plating layer, a palladium plating layer, a nickel plating layer, a zinc plating layer and a chromium plating layer. This plating layer may be a single layer or a composite plating layer composed of a laminate of plural plating layers. Further, the metal plating layer may be a pure metal layer composed of the above metal or may have a diffusion layer wherein another metal has been diffused. For forming a diffusion layer, on a surface of a metal (or metal plating layer) to be diffused is formed a plating layer composed of a metal for forming a diffusion layer, and then, for example, heat treatment is carried out, whereby the metal in the lower layer and the metal in the upper layer mutually diffused to form a diffusion layer.

In a single printed wiring board, these layers are usually made of the same metal. However, such metal plating layers do not necessarily have to be formed from the same metal in a single printed wiring board, and the metals for forming the plating layers may be different from one another depending upon the terminals.

The plating layer can be formed by a usual plating method such as electroplating or electroless plating.

Although the average thickness of the plating layer varies depending upon the type of the plating layer formed, it is usually in the range of 5 to 12 μm. When the wiring pattern has plural plating layers, the above-mentioned average thickness is the total thickness of the plating layers formed on the wiring pattern.

Examples of sectional shapes of the wiring patterns formed as above are shown in FIGS. 3(1) to 3(4). Referring to FIG. 3, numeral 11 designates an insulating film, numeral 12 designates a base metal layer, numeral 20 designates a conductive metal layer, and numeral 16 designates a plating layer.

The terminal of the printed wiring board produced as above and an electrode such as a bump electrode formed on an electronic component are electrically connected to each other to mount the electronic component such as an IC chip, and the electronic component including the connected portion and its circumference are sealed with a resin, whereby a semiconductor device can be produced.

In the printed wiring board and the semiconductor device of the present invention, the metal derived from the etching solutions used in plural etching steps is removed by the use of an aqueous solution containing a reducing substance. Therefore, the amount of the metal derived from the etching solutions and present on the wiring pattern formed and between the wiring patterns can be reduced to an extremely small amount of not more than 0.05 μg/cm², preferably 0.000002 to 0.003 μg/cm². Consequently, migration attributable to the residual metal hardly takes place, and contamination of a plating solution used in the subsequent step by the residual metal does not occur. Thus, a printed wiring board having extremely high reliability can be obtained.

As described above, in the printed wiring board and the semiconductor device of the present invention, the amount of the residual metal derived from the etching solution and present on the wiring pattern and the insulating film is extremely small. In the printed wiring board and the semiconductor device of the present invention, therefore, variation of electrical resistance between the wiring patterns due to migration or the like is extremely reduced. That is to say, in the printed wiring board and the semiconductor device of the present invention, the amount of the residual metal derived from the etching solution is extremely small, migration or the like attributable to the residual metal hardly takes place, and a substantial change is not observed between the insulation resistance before a voltage is applied and the insulation resistance after a voltage is continuously applied for a long period of time, so that the printed wiring board has extremely high reliability.

The printed wiring board of the present invention is suitable as a printed wiring board having a wiring pattern (or lead) width of not more than 30 μm, preferably 25 to 5 μm, and a pitch width of not more than 50 μm, preferably 40 to 20 μm.

Examples of such printed wiring boards include printed wiring board (PWB), FPC (flexible printed circuit), TAB (tape automated bonding) tape, COF (chip on film), CSP (chip size package), BGA (ball grid array) and μ-BGA (μ-ball grid array).

As the printed wiring board of the present invention, a printed wiring board in which a polyimide film is used as the insulating film and on a surface of the insulating film a wiring pattern is formed is mainly described. The semiconductor device of the present invention is produced by mounting an electronic component on the wiring pattern of the printed wiring board and sealing the circumference of the mounted electronic component with a resin, and the semiconductor device also has extremely high reliability.

### EXAMPLES

The printed wiring board of the present invention and the process for producing the printed wiring board are further described with reference to the following examples, but it should be construed that the present invention is in no way limited to those examples. The insulation resistance values described hereinafter are values all measured at room temperature outside a constant-temperature constant-humidity bath.

### Example 1

One surface of a polyimide film having a width of 35 mm and an average thickness of 38 μm (available from Ube Industries, Ltd., Upilex S) was subjected to roughening treatment by back sputtering, and then a nickel-chromium alloy was sputtered under the following conditions to form a chromium-nickel alloy layer having an average thickness of 40 nm as a base metal layer. That is to say, a polyimide film of 38 μm thickness was treated under the conditions of 100° C. and 3×10⁻⁵ Pa for 10 minutes, then the apparatus was degassed to a pressure of 0.5 Pa at 100° C., and a chromium-nickel alloy was sputtered to form a base metal layer.

On the base metal layer formed as above, copper was deposited by electroplating to form an electrodeposited copper layer (conductive metal layer) having a thickness of 8 μm.

The surface of the electrodeposited copper layer thus formed was coated with a photosensitive resin, and the photosensitive resin was exposed to light and developed to form a pattern for a comb-shaped electrode having a wiring pitch of 30 μm (line width: 15 μm, space width: 15 μm). Using the pattern as a masking material, the electrodeposited copper layer was etched for 30 seconds with a cupric chloride etching solution containing 100 g/liter of HCl and having a concentration of 12% to form a wiring pattern.

The masking material composed of the photosensitive resin and present on the resulting wiring pattern was removed by treating it with a NaOH+NaCO₃ solution at 40° C. for 30 seconds.

Then, treatment using a K₂S₂O₈+H₂SO₄ solution as a pickling solution was carried out at 30° C. for 10 seconds to pickle the electrodeposited copper layer and the base metal layer (Ni—Cr alloy).

Then, the resulting film carrier tape was treated with a solution containing 17 g/liter of HCl and 17 g/liter of H₂SO₄ as a first treating solution at 50° C. for 30 seconds to dissolve Ni of the base metal layer composed of a Ni—Cr alloy.

Using a H₂S₂O₈+H₂SO₄ solution as a microetching solution, the Cu conductor was selectively dissolved in such a manner that the treatment depth toward the inside from the edge of the wiring pattern became 0.3 μm (retreat of Cu conductor).

Further, treatment using a potassium permanganate (40 g/liter)+KOH (20 g/liter) solution as a second treating solution was carried out at 65° C. for 30 seconds to dissolve Cr contained in the base metal layer. This second treating solution could dissolve and remove chromium contained in the base metal layer, and besides, it could oxidize and passivate chromium remaining in a slight amount.

Then, in order to remove residual Mn adhering to the insulating film and the pattern, the board was cleaned with an oxalic acid aqueous solution containing 40 g/liter of oxalic acid dihydrate ((COOH)₂-2H₂O) at 40° C. for 1 minute. Thus, the residual Mn was dissolved and removed. Thereafter, the board was rinsed in pure water at 23° C. for 15 seconds.

In the case where the board was cleaned with the oxalic acid aqueous solution at 40° C. for 1 minute as above, the amount of the residual Mn adhering to the board was 0.0003 μg/cm². In contrast therewith, in the case where cleaning with the oxalic acid aqueous solution was not carried out (Reference Example 1), the amount of the residual Mn was 0.14 μg/cm². In the case where cleaning with the oxalic acid aqueous solution is not carried out, therefore, a considerable amount of Mn remains on the board, and there is a fear that this Mn is not removed in the subsequent step and a printed wiring board with the remaining Mn is produced. This sometimes causes deterioration of quality of the printed wiring board. Moreover, the remaining Mn contaminates a chemical solution used in the subsequent step and sometimes causes lowering of appearance or quality of the printed wiring board.

After the wiring pattern was formed as above, the wiring pattern was subjected to electroless tin plating to be a thickness of 0.01 μm.

After the wiring pattern was concealed with the tin plating layer as above, a solder resist layer was formed in such a manner that a connecting terminal and an outer connecting terminal were exposed.

The inner connecting terminal and the outer connecting terminal exposed from the solder resist layer were subjected to Sn plating to be a thickness of 0.5 μm, and they were heated to form a prescribed pure Sn layer (total thickness of Sn plating layers: 0.51 μm, thickness of pure Sn layer: 0.25 μm).

The wiring pattern thus formed had a sectional shape closely resembling a shape shown in FIG. 3(2).

To the printed wiring board with a comb-shaped electrode prepared as above was applied a voltage of 40 V under the conditions of 85° C. and 85% RH to perform a 1000-hr conduction test (HHBT). This conduction test is an acceleration test, and in this test, the time up to the occurrence of short-circuit (e.g., time until the insulation resistance value becomes less than 1×10⁸Ω) is set to about 1000 hours. A printed wiring board having an insulation resistance value of less than 1×10⁸Ω after a lapse of 1000 hours cannot be used as a general board. A printed wiring board having an insulation resistance value of less than 1×10¹⁴Ω after a lapse of 1000 hours is liable to become a problem in the practical use.

The printed wiring board produced in this Example 1 had an insulation resistance of 6×10¹⁴Ω before the insulation reliability test and had an insulation resistance of 6×10¹⁴Ω after the insulation reliability test, so that a substantial difference in the insulation resistance accompanying the application of a voltage was not observed between them.

On the other hand, the sample obtained without performing oxalic acid treatment (Reference example 1) had an insulation resistance, as measured after the insulation reliability test, of 1.0×10¹⁴Ω. That is to say, the insulation reliability of the printed wiring board was improved by performing the treatment using oxalic acid.

The results are set forth in Table 1.

### Example 2

One surface of a polyimide film having an average thickness of 38 μm (available from Ube Industries, Ltd., Upilex S) was subjected to roughening treatment by back sputtering, and then a nickel-chromium alloy was sputtered under the following conditions to form a chromium-nickel alloy layer having an average thickness of 40 nm as a base metal layer. That is to say, a polyimide film of 38 μm thickness was treated under the conditions of 100° C. and 3×10⁻⁵ Pa for 10 minutes, then the pressure in the apparatus was set to 0.5 Pa at 100° C., and a chromium-nickel alloy was sputtered to form a base metal layer.

On the base metal layer formed as above, copper was deposited by electroplating to form an electrodeposited copper layer (electroplating copper layer) having a thickness of 8 μm.

The surface of the electrodeposited copper layer thus formed was coated with a photosensitive resin, and the photosensitive resin was exposed to light and developed to form a pattern for a comb-shaped electrode having a wiring pitch of 30 μm (line width: 15 μm, space width: 15 μm). Using the pattern as a masking material, the electrodeposited copper layer was etched for 30 seconds with a cupric chloride etching solution containing 100 g/liter of HCl and having a concentration of 12% to form a wiring pattern having a shape similar to the shape of the pattern composed of the photosensitive resin.

The masking material composed of the photosensitive resin and present on the resulting wiring pattern was removed by treating it with a NaOH+NaCO₃ solution at 40° C. for 30 seconds.

Then, treatment using a K₂S₂O₈+H₂SO₄ solution as a first treating solution was carried out at 30° C. for 10 seconds to pickle copper and the base metal layer (Ni—Cr alloy).

Then, using a potassium permanganate (concentration: 40 g/liter)+KOH (20 g/liter) etching solution as a second treating solution, the Ni—Cr alloy projected part was passivated at 40° C. over a period of 1 minute. Further, chromium remaining in a slight amount between the wirings was dissolved as much as possible, and chromium that had not been removed was passivated as chromium oxide.

Then, in order to remove residual Mn adhering to the film and the pattern of the wiring board, the board was cleaned with an oxalic acid aqueous solution containing 40 g/liter of oxalic acid dihydrate ((COOH)₂₋₂H₂O) at 40° C. for 1 minute. Thus, the residual Mn was dissolved and removed. Thereafter, the board was rinsed in pure water at 23° C. for 15 seconds.

In the case where the board was cleaned with the oxalic acid aqueous solution at 40° C. for 1 minute as above, the amount of the residual Mn adhering to the board was 0.00056 μg/cm². In contrast therewith, in the case where cleaning with the oxalic acid aqueous solution was not carried out (Reference Example 2), the amount of the residual Mn was 0.11 μg/cm².

Then, Sn plating was carried out to be a thickness of 0.5 μm, and heating was carried out to form a prescribed pure Sn layer.

The wiring pattern thus formed had a sectional shape closely resembling a shape shown in FIG. 3(1).

To the printed wiring board with a comb-shaped electrode prepared as above was applied a voltage of 40 V under the conditions of 85° C. and 85% RH to perform a 1000-hr conduction test (HHBT). The printed wiring board had an insulation resistance of 5×10¹⁴Ω before the insulation reliability test and had an insulation resistance of 5×10¹⁴Ω after the insulation reliability test, so that a substantial difference in the insulation resistance accompanying the application of a voltage was not observed between them.

On the other hand, the sample obtained without performing oxalic acid treatment (Reference Example 2) had an insulation resistance, as measured after the insulation reliability test, of 3.5×10¹⁴Ω. That is to say, the insulation reliability of the printed wiring board was improved by performing the treatment using oxalic acid.

The results are set forth in Table 1.

### Example 3

One surface of a polyimide film having an average thickness of 38 μm (available from Ube Industries, Ltd., Upilex S) was subjected to roughening treatment by back sputtering, and then a nickel-chromium alloy was sputtered under the following conditions to form a chromium-nickel alloy layer having an average thickness of 40 nm as a base metal layer. That is to say, a polyimide film of 38 μm thickness was treated under the conditions of 100° C. and 3×10⁻⁵ Pa for 10 minutes, and then sputtering of a chromium-nickel alloy was carried out in an apparatus adjusted to a temperature of 100° C. and a pressure of 0.5 Pa, to form a base metal layer.

On the base metal layer formed as above, copper was deposited by electroplating to form an electrodeposited copper layer (electroplating copper layer) having a thickness of 8 μm.

The surface of the electrodeposited copper layer thus formed was coated with a photosensitive resin, and the photosensitive resin was exposed to light and developed to form a pattern for a comb-shaped electrode having a wiring pitch of 30 μm (line width: 15 μm, space width: 15 μm). Using the pattern as a masking material, the electrodeposited copper layer was etched for 30 seconds with a cupric chloride etching solution containing 100 g/liter of HCl and having a concentration of 12% to form a wiring pattern having a shape similar to the shape of the pattern composed of the photosensitive resin.

The masking material composed of the photosensitive resin and present on the resulting wiring pattern was removed by treating it with a NaOH+Na₂CO₃ solution at 40° C. for 30 seconds.

Then, treatment using a K₂S₂O₈+H₂SO₄ solution as a pickling solution was carried out at 30° C. for 10 seconds to pickle copper and the base metal layer (Ni—Cr alloy).

Then, using a 15% HCl+15% H₂SO₄ solution as a first treating solution capable of dissolving Ni, Ni of the Ni—Cr alloy projected part 26 was dissolved at 50° C. over a period of 30 seconds, and polyimide (i.e., insulating film) between the wiring patterns was exposed.

Then, treatment using a potassium permanganate (40 g/liter)+KOH (20 g/liter) solution as a second treating solution capable of dissolving Cr and polyimide was carried out to dissolve and remove the metal present between the wiring patterns together with the polyimide film of 50 nm thickness present below the metal.

Then, in order to remove residual Mn adhering to the film and the pattern of the wiring board, the board was cleaned with an oxalic acid aqueous solution containing 40 g/liter of oxalic acid dihydrate ((COOH)₂-2H₂O) at 40° C. for 1 minute. Thus, the residual Mn was dissolved and removed. Thereafter, the board was rinsed in pure water at 23° C. for 15 seconds.

In the case where the board was cleaned with the oxalic acid aqueous solution at 40° C. for 1 minute as above, the amount of the residual Mn adhering to the board was 0.00028 μg/cm². In contrast therewith, in the case where cleaning with the oxalic acid aqueous solution was not carried out (Reference Example 3), the amount of the residual Mn was 0.056 μg/cm².

Then, a solder resist layer was formed in such a manner that an inner connecting terminal and an outer connecting terminal were exposed. The inner connecting terminal and the outer connecting terminal exposed from the solder resist layer were subjected to Sn plating to be a thickness of 0.5 μm, and they were heated to form a prescribed pure Sn layer.

The wiring pattern thus formed had a sectional shape closely similar to a shape shown in FIG. 3(3).

To the printed wiring board with a comb-shaped electrode prepared as above was applied a voltage of 40 V under the conditions of 85° C. and 85% RH to perform a 1000-hr conduction test (HHBT). The printed wiring board had an insulation resistance of 7×10¹⁴Ω before the insulation reliability test and had an insulation resistance of 8×10¹⁴Ω after the insulation reliability test, so that a substantial difference in the insulation resistance accompanying the application of a voltage was not observed between them.

On the other hand, the sample obtained without performing oxalic acid treatment (Reference Example 3) had an insulation resistance, as measured after the insulation reliability test, of 4.6×10¹⁴Ω. That is to say, the insulation reliability of the printed wiring board was improved by performing the treatment using oxalic acid.

The results are set forth in Table 1.

TABLE 1

| | | | | | | | | | Reducing aqueous | | Sn | HHBT |
|---|---|---|---|---|---|---|---|---|---|---|---|---|
| | | Base | | | | | | | solution treatment | | plating | Insulation |
| | | metal | | | Etching solution | | | | Oxalic | Amount of | layer | resistance |
| | | layer | Copper plating layer | | | First | | Second | acid conc. | residual | Metal | after |
| | | Nickel- | | Thick- | Cu | treating | Micro- | treating | Treatment | Mn | thick- | lapse of |
| | Polyimide | Chromium | Metal | ness | etching | solution | etching | solution | conditions | (μg/cm²) | ness | 1000 hrs |
| Ex. 1 | 38 μm | 40 nm | Electro- | 8 μm | Cupuric | 15% HCl + | K₂S₂O₈ + | KMnO₄ + | 40 g/L | 0.0003 | 0.5 μm | 6 × 10¹⁴ Ω |
| | | | deposited | | chloride | 15% H₂SO₄ | H₂SO₄ | KOH | 40 · Cx1min | | | |
| | | | copper | | | | | | | | | |
| Ref | 38 μm | 40 nm | Electro- | 8 μm | Cupuric | 15% HCl + | K₂S₂O₈ + | KMnO₄ + | None | 0.14 | 0.5 μm | 1.0 × 10¹⁴ Ω |
| Ex. 1 | | | deposited | | chloride | 15% H₂SO₄ | H₂SO₄ | KOH | | | | |
| | | | copper | | | | | | | | | |
| Ex. 2 | 38 μm | 40 nm | Electro- | 8 μm | Cupuric | K₂S₂O₈ + | None | KMnO₄ + | 40 g/L | 0.00056 | 0.5 μm | 5 × 10¹⁴ Ω |
| | | | deposited | | chloride | H₂SO₄ | | KOH | 40 · Cx1min | | | |
| | | | copper | | | | | | | | | |
| Ref | 38 μm | 40 nm | Electro- | 8 μm | Cupuric | K₂S₂O₈ + | None | KMnO₄ + | None | 0.11 | 0.5 μm | 3.5 × 10¹⁴ Ω |
| Ex. 2 | | | deposited | | chloride | H₂SO₄ | | KOH | | | | |
| | | | copper | | | | | | | | | |
| Ex. 3 | 38 μm | 40 nm | Electro- | 8 μm | Cupuric | 15% HCl + | None | KMnO₄ + | 40 g/L | 0.00028 | 0.5 μm | 8 × 10¹⁴ Ω |
| | | | deposited | | chloride | 15% H₂SO₄ | | KOH | 40 · Cx1min | | | |
| | | | copper | | | | | | | | | |
| Ref | 38 μm | 40 nm | Electro- | 8 μm | Cupuric | 15% HCl + | None | KMnO₄ + | None | 0.056 | 0.5 μm | 4.6 × 10¹⁴ Ω |
| Ex. 3 | | | deposited | | chloride | 15% H₂SO₄ | | KOH | | | | |
| | | | copper | | | | | | | | | |

### INDUSTRIAL APPLICABILITY

In the printed wiring board of the present invention, the metal derived from the etching solution is removed by treating the wiring board with an aqueous solution containing a reducing substance, as described above. Therefore, the amount of the residual metal derived from the etching solution, which is present on the surface of the printed wiring board, is extremely small, occurrence of migration attributable to the residual metal can be prevented, and a printed wiring board and a semiconductor device having very high reliability can be obtained. Further, because the metal derived from the etching solution is removed in the production of the printed wiring board, a treating solution used in the subsequent step and the production apparatus are not contaminated with the metal derived from the etching solution, and a printed wiring board and a semiconductor device can be efficiently produced. Moreover, because the metal derived from the etching solution can be efficiently removed by the use of a treating solution containing a reducing substance, the water rinsing step can be shortened, and by adopting the production process of the present invention, a printed wiring board can be efficiently produced.

1. A process for producing a printed wiring board, comprising selectively etching a base film which comprises an insulating film, a base metal layer formed on at least one surface of the insulating film and a conductive metal layer formed on the base metal layer through plural etching steps comprising a conductive metal etching step for mainly dissolving the conductive metal and a base metal etching step for mainly dissolving the base metal, to form a wiring pattern, and then bringing the insulating film having the wiring pattern formed thereon into contact with a reducing aqueous solution containing a reducing substance.

2. The process for producing a printed wiring board as claimed in claim 1, wherein the base film is brought into contact with an etching solution that dissolves the conductive metal to form a wiring pattern, then brought into contact with a first treating solution that dissolves the metal for forming the base metal layer, subsequently brought into contact with a microetching solution that selectively dissolves the conductive metal, then brought into contact with a second treating solution that has a chemical composition different from that of the first treating solution and acts on the base metal layer-forming metal with higher selectivity than on the conductive metal, and further brought into contact with a reducing aqueous solution containing a reducing substance.

3. The process for producing a printed wiring board as claimed in claim 1, wherein the conductive metal layer of the base film is selectively removed by etching to form a wiring pattern, and thereafter the base film is treated with a treating solution capable of dissolving and/or passivating the metal for forming the base metal layer and then brought into contact with a reducing aqueous solution containing a reducing substance.

4. The process for producing a printed wiring board as claimed in claim 1, wherein the base film is treated with a first treating solution capable of dissolving Ni contained in the base metal layer, then treated with a second treating solution capable of dissolving Cr contained in the base metal layer and capable of removing the base metal layer on the insulating film to remove, together with a surface layer of the insulating film, a sputtering metal remaining on the surface layer of the insulating film on which no wiring pattern has been formed, and further brought into contact with a reducing aqueous solution containing a reducing substance.

5. The process for producing a printed wiring board as claimed in claim 1, wherein the reducing substance contained in the reducing aqueous solution is an organic acid having reducing ability or its salt.

6. The process for producing a printed wiring board as claimed in claim 5, wherein the organic acid having reducing ability is at least one organic acid selected from the group consisting of ascorbic acid, oxalic acid, citric acid and an organic carboxylic acid.

7. The process for producing a printed wiring board as claimed in claim 1, wherein a metal or a metal compound derived from an oxidizing inorganic compound that is potassium permanganate and/or sodium permanganate is adhering to a surface of a wiring board having a wiring pattern formed thereon that is to be brought into contact with the reducing aqueous solution.

8. The process for producing a printed wiring board as claimed in claim 1, wherein after the base film is brought into contact with the reducing aqueous solution, the base film is rinsed in running water for not shorter than 2 seconds.

9. The process for producing a printed wiring board as claimed in claim 1, wherein the amount of a residual metal derived from the etching solution on the printed wiring board produced is not more than 0.05 μg/cm².

10. The process for producing a printed wiring board as claimed in claim 9, wherein the amount of the residual metal derived from the etching solution on the printed wiring board produced is in the range of 0.000002 to 0.03 μg/cm².

11. The process for producing a printed wiring board as claimed in claim 1, wherein the base metal layer comprises nickel and/or chromium.

12. The process for producing a printed wiring board as claimed in claim 1, wherein the conductive metal layer is formed from copper or a copper alloy.

13. The process for producing a printed wiring board as claimed in claim 1, wherein the insulating film is a polyimide film.

14. A printed wiring board having a wiring pattern formed by selectively etching a base metal layer and a conductive metal layer, which are formed on at least one surface of an insulating film, through plural etching steps, wherein:
the amount of a residual metal derived from the etching solution on the printed wiring board is not more than 0.05 μg/cm².

15. The printed wiring board as claimed in claim 14, wherein the width of the lower end of the conductive metal layer in a section of the wiring pattern is smaller than the width of the upper end of the base metal layer in a section thereof, and the amount of the residual metal derived from the etching solution on the printed wiring board is not more than 0.05 μg/cm².

16. The printed wiring board as claimed in claim 14, wherein the base metal layer that constitutes the wiring pattern is formed so as to protrude in the width direction than the conductive metal layer that constitutes the wiring pattern, and the amount of the residual metal derived from the etching solution on the printed wiring board is not more than 0.05 μg/cm².

17. The printed wiring board as claimed in claim 14, wherein the thickness of the insulating film on which no wiring pattern has been formed is smaller by 1 to 100 nm than the thickness of the insulating film on which the wiring pattern has been formed, and the amount of the residual metal derived from the etching solution on the printed wiring board is not more than 0.05 μg/cm².

18. The printed wiring board as claimed in claim 14, wherein the metal derived from the etching solution is a metal that is composed of an oxidizing metal compound contained in the etching solution.

19. The printed wiring board as claimed in claim 14, wherein the metal that is composed of the oxidizing metal compound is manganese.

20. The printed wiring board as claimed in claim 14, wherein the amount of the residual metal derived from the etching solution is in the range of 0.000002 to 0.03 μg/cm².

21. The printed wiring board as claimed in claim 14, wherein the base metal layer comprises nickel and/or chromium.

22. The printed wiring board as claimed in claim 14, wherein the conductive metal layer is formed from copper or a copper alloy.

23. The printed wiring board as claimed in claim 14, wherein the insulating film is a polyimide film.

24. A semiconductor device comprising an electronic part mounted on the printed wiring board of claim 14.
